(19) United States
(12) Patent Application Publication
(10) Pub. No.: US 2006/0284161 A1
(43) Pub. Date: Dec. 21, 2006

(54) Light source module and vehicle lamp

(75) Inventor: Tsukasa Tokida, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: KOITO MANUFACTURING CO., LTD.

(21) Appl. No.: 11/451,404

(22) Filed: Jun. 13, 2006

(30) Foreign Application Priority Data
Jun. 15, 2005 (JP) P. 2005-175274

(51) Int. Cl. H01L 29/06; H01L 31/00

(52) U.S. Cl. 257/13

(57) ABSTRACT

A light source module is provided with a semiconductor light emitting element disposed in a hollow airtight region within a cover fixed to a circuit board, and electrodes which are disposed outside of the airtight region and supplies a current to the semiconductor light emitting element. The circuit board is provided with a non-conductive layer serving as a base member and having non-conductivity and also provided with conductive patterns for coupling the semiconductor light emitting element to the electrodes. Then, the cover is fixed on the non-conductive layer.

The present application claims foreign priority based on Japanese Patent Application No. P.2005-175274, filed on Jun. 15, 2005, the contents of which are incorporated herein by reference.

### BACKGROUND OF THE INVENTION

1. Field of the Invention

The present invention relates to a light source module and a vehicle lamp and, more particularly, relates to a technical field in which a cover is fixed to a non-conductive layer having no conductivity of a circuit board, thereby to intend to improve the reliability of the fixing property of the cover with respect to the circuit board.

2. Related Art

There is a light source module provided with a semiconductor light emitting element such as a light emitting diode (LED) as a light source. Such a light source module is provided, for example, in a vehicle lamp that irradiates a light emitted from a light source as an illumination light through a projection lens.

Disclosed in JP-A-2004-207660 is a light source module in which a light emitting diode is mounted on a conductive pattern of a circuit board and the light emitting diode is closed tightly by a glass lens (cover). The glass lens is configured by a sealed portion which is formed in a hemispherical shape so as to cover the light emitting diode and a fixing portion of a flange shape which is extended outward from the peripheral edge of the sealed portion, whereby the fixing portion is fixed on the conductive pattern by means of an adhesive etc.

Since the conductive pattern of the circuit board is formed by metal material such as gold or copper, a linear expansion coefficient of the conductive pattern largely differs from that of the glass lens. Thus, when the temperature changes, the fixing intensity degrades due to the difference of the linear expansion coefficients between the conductive pattern and the glass lens, so that there may arise such a phenomenon that the glass lens is peeled off or fallen out the circuit board.

Further, the cover may be configured by a resin lens formed by resin such as fluorine resin or silicon resin in place of the glass lens. In this case, also the linear expansion coefficient of the conductive pattern largely differs from that of the resin lens, the fixing intensity degrades like the aforesaid case.

### SUMMARY OF THE INVENTION

One or more embodiments of the present invention provide a light source module and a vehicle lamp which can improve the reliability of the fixing property of a cover with respect to a circuit board.

In accordance with one or more embodiments of the present invention, a light source module is provided with: a circuit board including a non-conductive layer serving as a base member and having non-conductivity and also having conductive patterns for coupling a semiconductor light emitting element to a electrodes; and a cover fixed on the non-conductive layer.

In accordance with one or more embodiments of the present invention, a vehicle lamp is provided with a source module having a semiconductor light emitting element which is disposed in a hollow airtight region within a cover fixed to a circuit board, and electrodes which are disposed outside of the airtight region and supplies a current to the semiconductor light emitting element. In the vehicle lamp, the circuit board is provided with a non-conductive layer serving as a base member and having non-conductivity and also provided with conductive patterns for coupling the semiconductor light emitting element to the electrodes, and the cover is fixed on the non-conductive layer.

Thus, according to the light source module and the vehicle lamp according to the embodiments, the cover and the non-conductive layer, the difference of the linear expansion coefficient being small therebetween, are fixed.

In accordance with one or more embodiments of the present invention, a light source module is provided with a semiconductor light emitting element which is disposed in a hollow airtight region within a cover fixed to a circuit board, and electrodes which are disposed outside of the airtight region and supplies a current to the semiconductor light emitting element. In the light source module, the circuit board is provided with a non-conductive layer serving as a base member and having non-conductivity and also provided with conductive patterns for coupling the semiconductor light emitting element to the electrodes, and the cover is fixed on the non-conductive layer.

Thus, since the difference of the linear expansion coefficient is small between the both members to be fixed, that is, the cover and the non-conductive layer, the fixing intensity between the circuit board and the cover hardly reduces even when the temperature changes. Therefore, even when the temperature changes, there does not arise such a phenomenon that the cover is peeled off or fallen out the circuit board.

Moreover, in accordance with one or more embodiments of the present invention, the cover may be formed by glass, a low-melting glass may be disposed between the glass and the non-conductive layer, and the low-melting glass may be molten to fix the cover to the non-conductive layer. Thus, the fixing can be performed surely since the difference of the linear expansion coefficient is small between the material of the non-conductive layer and the low-melting glass and also the difference of the linear expansion coefficient is small between the low-melting glass and the cover. Further, even when the temperature changes, such a phenomenon that the cover is peeled off or fallen out the circuit board can be prevented from occurring.

Moreover, in accordance with one or more embodiments of the present invention, a multi-layer board configured by laminating a plurality of the non-conductive layers may be used as the circuit board, and conductive patterns formed on the non-conductive layers may be coupled through vias. Thus, the configuration of the light source module is simple and so the simplification of the structure of the light source module and the suppression of the manufacturing cost can be realized.

Moreover, in accordance with one or more embodiments of the present invention, a surface of the conductive pattern on which the semiconductor light emitting element is mounted may be disposed at a position same as or higher than a surface of the non-conductive layer on which the cover is fixed. Thus, a light beam directed to the side direction among light beams emitted from the semiconductor light emitting element can not be shielded by the non-conductive layer and so the utilizing efficiency of the light can be improved.

Further, in accordance with one or more embodiments of the present invention, in a vehicle lamp in which a light emitted from a light source module disposed within a lamp housing is irradiated as an illumination light through a projection lens, the light source module is provided with: a semiconductor light emitting element which is disposed in a hollow airtight region within a cover fixed to a circuit board; and electrodes which are disposed outside of the airtight region and supplies a current to the semiconductor light emitting element. The circuit board is provided with a non-conductive layer serving as a base member and having non-conductivity and also provided with conductive patterns for coupling the semiconductor light emitting element to the electrodes, and the cover is fixed on the non-conductive layer.

Thus, since the difference of the linear expansion coefficient is small between the both members to be fixed, that is, the cover and the non-conductive layer, the fixing intensity between the circuit board and the cover hardly reduces even when the temperature changes. Therefore, even when the temperature changes, there does not arise such a phenomenon that the cover is peeled off or fallen out the circuit board. Thus, it is always possible to secure a good illumination state as to an illumination light irradiated from the vehicle lamp.

Other aspects and advantages of the invention will be apparent from the following description and the appended claims.

### BRIEF DESCRIPTION OF THE DRAWINGS

FIG. 1 is an enlarged exploded perspective view of a light source module according to an exemplary embodiment of the invention.

FIG. 2 is an enlarged sectional view of the light source module.

FIG. 3 is a schematic sectional view of a vehicle lamp according to an exemplary embodiment of the invention.

### DETAILED DESCRIPTION OF THE EXEMPLARY EMBODIMENTS

Exemplary embodiments of the invention will be described with reference to the accompanying drawings.

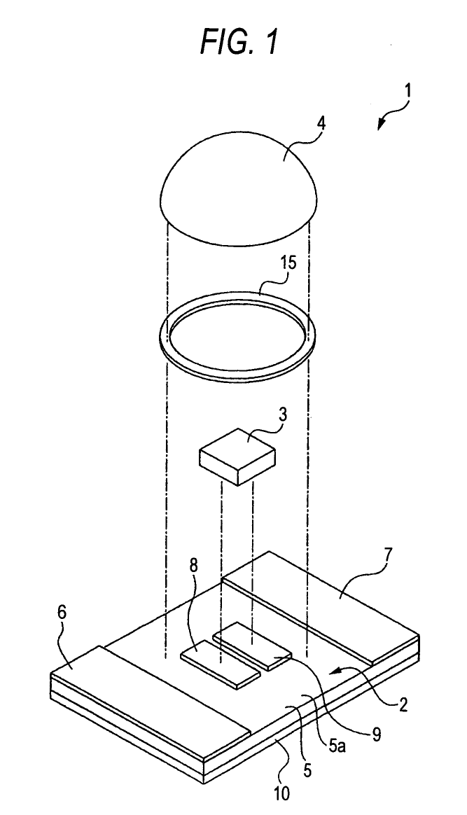

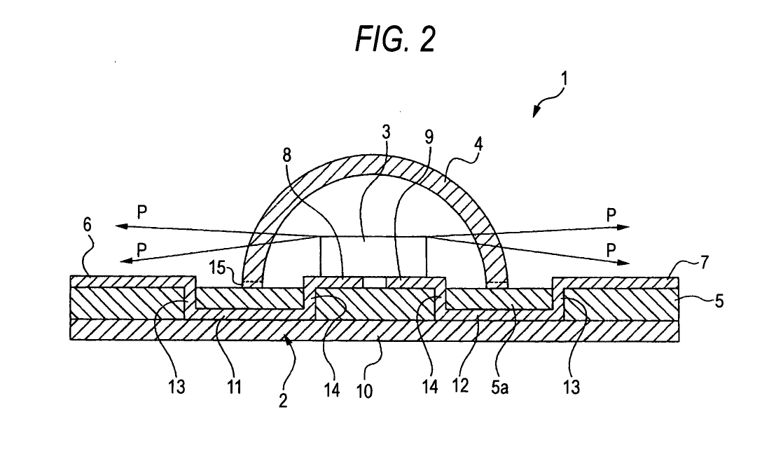

A light source module 1 is provided with a circuit board 2, a semiconductor light emitting element 3 such as an LED chip and a cover 4 (see FIGS. 1 and 2).

The circuit board 2 is a multi-layer board or substrate configured by two layers which is formed by laminating base members, for example, and the base members are provided as non-conductive layers 5, 6 having non-conductivity, respectively. As the circuit board 2, various kinds of boards such as a ceramic board (an aluminum nitride board, an alumina board, a mullite board, a glass ceramic board etc.), a glass epoxy board or an aluminum base board are employed.

Electrodes 6, 7 each formed by metal material such as gold or copper are respectively formed at the both end portions in the longitudinal direction on the non-conductive layer 5 positioned as the upper layer. The electrodes 6, 7 are provided as positive and negative electrodes, respectively. The electrodes 6, 7 are coupled to a not shown power source supply circuit.

At the center portion in the longitudinal direction of the non-conductive layer 5, conductive patterns 8 and 9 each formed by metal material such as gold or copper are provided in a manner of being separated in the longitudinal direction. Each of these conductive patterns 8 and 9 is provided as an element mounting portion. The area of each of the conductive patterns 8 and 9 is set to be smaller than the area of each of the electrodes 6 and 7. Thus, the surface of the non-conductive layer 5 is exposed

at the periphery of the conductive patterns 8, 9 and the exposed portion is formed as a fixing portion 5a.

On the non-conductive layer 10 positioned as the lower layer, conductive patterns 11 and 12 each formed by metal material such as gold or copper are provided at portions except for the both end portions and the center portion in the longitudinal direction thereof.

When the circuit board 2 is the aluminum nitride board, for example, the linear expansion coefficient of each of the non-conductive layers 5 and 10 is 4.4·10⁻⁶. The linear expansion coefficient of each of the electrodes 6, 7 and the conductive patterns 8, 9, 11, 12 is 14.2·10⁻⁶ when the material thereof is gold and 17.0·10⁻⁶ when the material thereof is copper.

The end portions at the inner sides of the electrodes 6, 7 formed on the non-conductive layer 5 are coupled to the end portions of the outer sides of the conductive patterns 11, 12 formed on the non-conductive layer 10 through vias 13, 13 provided at the non-conductive layer 5, respectively. The end portions at the outer sides of the conductive patterns 8, 9 formed on the non-conductive layer 5 are coupled to the end portions of the inner sides of the conductive patterns 11, 12 formed on the non-conductive layer 10 through vias 14, 14 provided at the non-conductive layer 5, respectively. Each of the vias 13, 13, 14 and 14 is formed by metal material such as gold or copper.

A light emitting diode formed by applying fluorescent material in a uniform film shape, for example, is employed as the semiconductor light emitting element 3. The semiconductor light emitting element 3 is fixed in a state that the lower surface thereof extends over the conductive patterns 8 and 9 and is coupled to the electrodes 6, 7 serving as positive and negative electrodes through the vias 14, 14, the conductive patterns 11, 12 and the vias 13, 13, respectively.

That is, the non-conductive layer 5 has a first and second surfaces. On the first surface, the cover 4 is fixed. The second surface is disposed on a reverse side of the first surface. On the first surface of the non-conductive layer 5, the conductive patterns 8, 9 (first conductive pattern) are formed in a hollow airtight region within the cover 4. The conductive patterns 11, 12 (second conductive pattern) are contact with the second surface of non-conductive layer 5. The vias 14 penetrate the non-conductive layer 5, and the conductive patterns 8, 9 are coupled with the conductive patterns 11, 12 through the vias 14.

Thereby, neither the conductive patterns 8, 9 nor the conductive patterns 11, 12 are formed between a contact surface of the cover 4 and the non-conductive layer 5.

The cover 4 is formed by glass, fluorine resin or silicon resin, for example. The linear expansion coefficient of the cover 4 is 3.5·10⁻⁶ when the cover is formed by glass. The cover 4 is formed in the hemispherical shape so as to cover the semiconductor light emitting element 3.

The cover 4 is fixed to the fixing portion 5a of the non-conductive layer 5. Since the cover 4 is fixed to the non-conductive layer 5, the semiconductor light emitting element 3 is disposed in the hollow airtight region within the cover 4. The cover 4 is fixed to the fixing portion 5a via a low-melting glass 15 which melting point is lower than that of the material of the cover 4. To be concrete, the cover is fixed to the fixing portion in a manner that the low-melting glass 15 is disposed between the lower surface of the cover 4 and the fixing portion 5a and then the low-melting glass 15 is molten.

The low-melting glass 15 is formed in a manner, for example, that powdered material is liquefied and then solidified in a sheet shape. The material of the low-melting glass 15 is desirably selected so as to have the linear expansion coefficient similar to those of the cover 4 and the non-conductive layer 5 of the circuit board 2 by taking the linear expansion coefficients thereof into consideration.

Since the cover 4 has the hemispherical shape, the contact surface of the cover 4 has a ring shape. The sheet shaped low-melting glass 15 is formed in a ring shape so as to correspond to the ring shape of the contact surface of the cover 4.

When the cover 4 is fixed to the non-conductive layer 5 by using the low-melting glass 15 in this manner, the fixing can be performed surely since the difference of the linear expansion coefficient is small between the material of the non-conductive layer 5 and the low-melting glass 15 and also the difference of the linear expansion coefficient is small between the low-melting glass 15 and the cover 4. Further, even when the temperature changes, there does not arise such a phenomenon that the cover 4 is peeled off or fallen out the circuit board 2.

As described above, the cover 4 may alternatively be formed by fluorine resin or silicon resin. In this case, the cover 4 is fixed to the non-conductive layer 5 by means of epoxy adhesive agent, for example, preferably.

As described above, according to the light source module 1, the cover 4 is fixed to the non-conductive layer 5 which linear expansion coefficient is smaller in the difference from the linear expansion coefficient of the cover 4 as compared with the conductive patterns 8, 9. Thus, since the difference of the linear expansion coefficient is small between the two members to be fixed, that is, the cover and the non-conductive layer 5, the fixing intensity between the circuit board 2 and the cover 4 hardly reduces even when the temperature changes. Therefore, even when the temperature changes, there does not arise such a phenomenon that the cover 4 is peeled off or fallen out the circuit board 2.

Further, since the configuration for fixing the cover 4 to the non-conductive layer 5 is realized in a manner that a multi-layer board is used as the circuit board 2 and the vias 13, 13, 14, 14 are formed at the non-conductive layer 5, the configuration of the light source module 1 is simple and so the simplification of the structure of the light source module 1 and the suppression of the manufacturing cost can be realized.

According to the light source module 1, since the vias 13, 13, 14, 14 are formed, the upper surfaces of the conductive patterns 8, 9 on which the semiconductor light emitting element 3 is mounted, that is, the mounting surface of the semiconductor light emitting element 3 is disposed at the position higher than the upper surface of the non-conductive layer 5, that is, the fixing surface of the cover 4.

In contrast, if the fixing surface of the non-conductive layer 5 is disposed at the position higher than the upper surfaces of the conductive patterns 8, 9, a light beam (P shown in FIG. 2) directed to the side direction among light beams emitted from the semiconductor light emitting element 3 is shielded by the non-conductive layer 5 and so the utilizing efficiency of the light is degraded. However, according to the exemplary embodiment, since the upper surfaces of the conductive patterns 8, 9 are disposed at the position higher than the fixing surface of the non-conductive layer 5, the light beam directed to the side direction can not be shielded by the non-conductive layer 5 and so the utilizing efficiency of the light can be improved.

The upper surfaces of the conductive patterns 8, 9 may be disposed at the same height as the fixing surface of the non-conductive layer 5. In this case, also, since the light beam directed to the side direction can not be shielded by the non-conductive layer 5, the utilizing efficiency of the light can be improved.

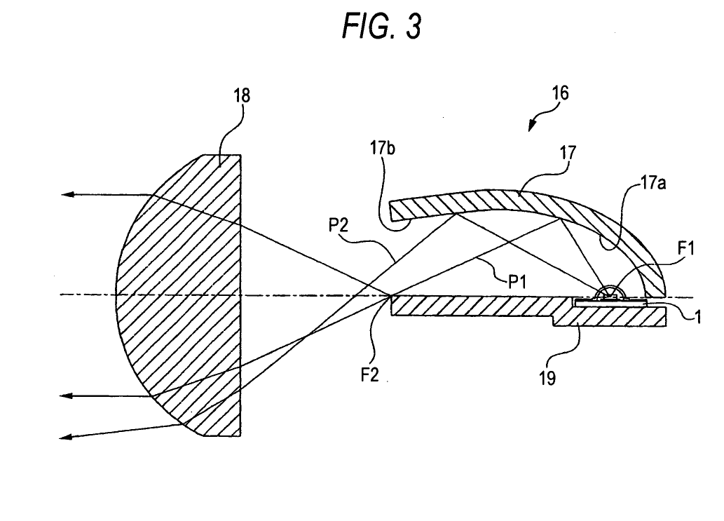

Next, the explanation will be made as to an example of the configuration of the vehicle lamp provided with the light source module 1 (see FIG. 3).

A vehicle lamp 16 includes a reflector 17 within which the light source module 1 is disposed and a projection lens 18 which irradiates the light emitted from the semiconductor light emitting element 3 as illumination light. The reflector 17 and the projection lens 18 are disposed within a not shown lamp housing which is configured by a lamp body and a transparent lens, for example.

In the case of using the light source module 1 for the vehicle lamp 16, the vehicle lamp 16 may be configured in a manner that the reflector 17, within which only the single light source module 1 is disposed, is disposed within the lamp housing. Alternatively, the vehicle lamp 16 may be configured in a manner that a plurality of the reflectors 17, within each of which the light source module 1 is disposed, are disposed within the lamp housing. In the case of using the plurality of the light source modules 1, the brightness of the illumination light irradiated from the vehicle lamp 16 can be made high according to the number of the light source modules 1. Further, in this case, since the degree of freedom of the arrangement of the light source modules 1 is improved, the degree of freedom of the shape of the vehicle lamp 16 can also be improved.

The reflector 17 includes a first reflection surface 17a positioned at the rear side of the reflector 17 and a second reflection surface 17b positioned at the front side of the first reflection surface 17a. The first reflection surface 17a is formed in an elliptical spherical shape and the second reflection surface 17b is formed in a slanted surface shape which is gradually inclined downward toward the front direction thereof. The semiconductor light emitting element 3 of the light source module 1 is disposed at the first focal point F1 of the first reflection surface 17a.

A light control member 19 of a planer shape, for example, is disposed within the reflector 17. The light source module 1 is mounted at the rear end portion of the light control member 19. The front end of the light control member 19 is almost made coincide with the second focal point F2 of the first reflection surface 17a of the reflector 17. Thus, the light emitted from the semiconductor light emitting element 3 and then reflected by the first reflection surface 17a (a light beam P1 shown in FIG. 3) is converged on the second focal point F2.

The focal point of the projection lens 18 made coincide with the second focal point F2. Thus, the light emitted from the semiconductor light emitting element 3 and then converged on the second focal point F2 is irradiated in the forward direction by the projection lens 18.

The light emitted from the semiconductor light emitting element 3 and then reflected by the second reflection surface 17b (a light beam P2 shown in FIG. 3) is directed in the forward direction of the second focal point F2, then transmits the lower end portion of the projection lens 18 and is irradiated as an illumination light. Thus, the illumination light transmitted through the projection lens 18 is irradiated in the forward direction as a composite illumination light of a main light flux reflected by the first reflection surface 17a and an additive light flux reflected by the second reflection surface 17b.

According to the vehicle lamp 16 configured in the aforesaid manner, since the light source module 1 which is formed by fixing the cover 4 to the non-conductive layer 5 is used, even when the temperature changes, such a phenomenon that the cover 4 is peeled off or fallen out the circuit board 2 can be prevented from occurring. Thus, it is always possible to secure a good illumination state as to an illumination light irradiated from the vehicle lamp 16.

The shapes and configurations of the respective portions shown in the aforesaid exemplary embodiments are merely an example of the concrete shapes and configurations performed at the time of practicing the invention and the technical range of the invention is not limited thereto.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

What is claimed is:

1. A light source module comprising:
a circuit board including a non-conductive layer and conductive patterns on the non-conductive layer;
a cover fixed on the non-conductive layer;
a semiconductor light emitting element disposed in a hollow airtight region within the cover; and
electrodes that is disposed outside of the airtight region and supplies a current to the semiconductor light emitting element through the conductive patterns.

2. The light source module according to claim 1, wherein the non-conductive layer is a base member of the circuit board.

3. The light source module according to claim 1, wherein the cover is formed by glass, and
a low-melting glass is disposed between the cover and the non-conductive layer, wherein the cover is fixed on the non-conductive layer by melting the low-melting glass.

4. The light source module according to claim 1, wherein the circuit board comprising a plurality of non-conductive layers and a plurality of conductive patterns formed on the non-conductive layers, and
the conductive patters are coupled through vias.

5. The light source module according to claim 4, wherein a surface of the conductive pattern on which the semiconductor light emitting element is mounted is disposed at a position same as or higher than a surface of the non-conductive layer on which the cover is joined.

6. The light source module according to claim 1, wherein the non-conductive layer comprises: a first surface on which the cover is fixed; and a second surface disposed on a reverse side of the first surface,
the conductive patterns comprises: a first conductive pattern formed on the first surface; and a second conductive pattern being contact with the second surface,
the first pattern is formed in the hollow airtight region, and
the first pattern and the second pattern is coupled through a via penetrating the non-conductive layer in the hollow airtight region.

7. The light source module according to claim 1, wherein the cover comprises a contact surface being contact with the non-conductive layer, and
any conductive patters are not formed between the contact surface and the non-conductive layer.

8. The light source module according to claim 7, wherein the cover is formed by glass, and
a low-melting glass is disposed between the cover and the non-conductive layer, wherein the cover is fixed on the non-conductive layer by melting the low-melting glass.

9. The light source module according to claim 8, wherein the cover is formed in a hemispherical shape,
the contact surface has a ring shape, and
the low-melting glass is formed in a ring shape.

10. A vehicle lamp comprising:
a lamp housing;
a projection lens; and
a light source module disposed within the lamp housing, wherein a light emitted from the light source module is irradiated through the projection lens,
wherein the light source module comprises:
a circuit board including a non-conductive layer and conductive patterns on the non-conductive layer;
a cover fixed on the non-conductive layer;
a semiconductor light emitting element disposed in a hollow airtight region within the cover; and
electrodes that is disposed outside of the airtight region and supplies a current to the semiconductor light emitting element through the conductive patterns.
